(19) United States
(12) Patent Application Publication
(10) Pub. No.: US 2008/0026539 A1
(43) Pub. Date: Jan. 31, 2008

(54) Capacitance element manufacturing method and etching method

(75) Inventors: Yutaka Kokaze, Shizuoka (JP); Masahisa Ueda, Shizuoka (JP); Mitsuhiro Endo, Shizuoka (JP); Koukou Suu, Shizuoka (JP)

Correspondence Address: KRATZ, QUINTOS & HANSON, LLP, 1420 K Street, N.W., Suite 400, WASHINGTON, DC, 20005, US

(73) Assignee: ULVAC, INC., Chigasaki-shi (JP)

(21) Appl. No.: 11/878,172

(22) Filed: Jul. 20, 2007

Related U.S. Application Data
(63) Continuation of application No. PCT/JP2006/300969, filed on Jan. 23, 2006.

(30) Foreign Application Priority Data
Jan. 28, 2005 (JP) 2005-020788

(51) Int. Cl. H01L 21/20

(52) U.S. Cl. 438/393; 257/E21.176

(57) ABSTRACT

An etching technique suitable for miniaturization is provided. An inorganic film is formed on an object to be subjected, the object having a lower electrode film, a dielectric film, and an upper electrode film laminated in that order on a substrate. A patterned organic resist film is disposed on the surface of the inorganic film. The inorganic film, upper electrode film, and the dielectric film are etched using the organic resist film as a mask, and then, the organic resist film is removed with the gas used to etch the lower electrode film; and the lower electrode film is etched using the inorganic film as a mask that has been exposed. Since the film serving as a mask is not re-formed, a fine pattern can be produced with good precision.

This is a Continuation of International Application No. PCT/JP2006/300969 filed Jan. 23, 2006. The entire disclosure of the prior application is hereby incorporated by reference herein in its entirety.

### BACKGROUND OF THE INVENTION

1. Field of the Invention

The present invention generally relates to the etching of a laminate structure of a noble metal, an oxide, and a noble metal, which is used in ferroelectric memories, piezoelectric MEMS devices, laminated capacitors, and so forth.

2. Discussion of the Relevant Art

Because of the need for semiconductor elements to be more highly integrated, more compact, and more energy efficient in recent years, there has also been an increasing need for technique for etching fine patterns. The noble metals, such as iridium, platinum, IrOx, PtO, SRO, ferroelectrics, such as (Ba,Sr)TiO₂, SrTiO₃, and other such paraelectric oxides, and SrBi₂Ta₂O₉, Bi₄Ti₃O₁₂, Pb(Zr,Ti)O₃, (Bi,La)₄Ti₅O₁₂ used in ferroelectric memories have low reactivity, and are redeposited on the side walls of the pattern during etching.

Redeposited material can be a cause of leakage between electrodes so that the photolithography step has to be performed every time a layer is etched. This means that the layers cannot be formed in the same size and width so that the pattern ends up being formed in a stepped shape.

The above-discussed conventional process is problematic in that it entailed more steps and the memory cell size become larger, so it is difficult to increase fineness. Also, when a laminate structure of a noble metal, an oxide, and a noble metal is etched all at once in a single photolithography step, the noble metal tended to re-adhere to the pattern side walls, and because the etching gas is different for each layer, there is no ideal mask material.

The above-mentioned related art is disclosed in Japanese Patent Laid-Open Publication JPA9-266200.

### SUMMARY OF THE INVENTION

In order to solve the above problems encountered by the prior art, the present invention provides an etching technique that is suited to increasing fineness.

The present invention provides a method for manufacturing a capacitance element to manufacture a capacitance element in which the lower electrode film, the dielectric film, and the upper electrode film are laminated, by etching an object (A). The object (A) includes a lower electrode film disposed above a substrate; a dielectric film disposed above part of the region of the lower electrode film; an upper electrode film disposed above the dielectric film; an inorganic film disposed above the upper electrode film; and an organic resist film disposed above the inorganic film, wherein at least part of the surface of the lower electrode film and the surface of the organic resist film are exposed. The manufacturing method comprises steps of exposing the object (A) to a plasma of a lower electrode etching gas, and etching the organic resist film and the lower electrode film exposed on the surface of the object (A) while the inorganic film is left.

The present invention is also a method for manufacturing a capacitance element, further including steps of etching an object (B) to be etched, the object (B) comprises the lower electrode film disposed above the substrate; the dielectric film disposed above the lower electrode film; the upper electrode film disposed above part of the region of the dielectric film; the inorganic film disposed above the upper electrode film; and an organic resist film disposed above the inorganic film, wherein at least part of the surface of the dielectric film and the surface of the organic resist film are exposed, the steps of etching the object (B) comprises exposing the object (B) to a plasma of a dielectric film etching gas, and etching the dielectric film exposed on the surface of the object (B) while the organic resist film is left, so as to form the object (A).

The present invention is also a method for manufacturing a capacitance element that further includes steps of etching an object (C) to be etched, the object (C) includes the lower electrode film disposed above the substrate; the dielectric film disposed above the lower electrode film; the upper electrode film disposed above the dielectric film; the inorganic film disposed above part of the region of the upper electrode film; and the organic resist film disposed above the inorganic film, wherein at least part of the surface of the upper electrode film and the surface of the organic resist film are exposed. The steps of etching the object (C) comprises exposing the object (C) to a plasma of an upper electrode film etching gas, and etching the upper electrode film exposed on the surface of the object (C) while the organic resist film is left so as to form the object (B).

The present invention is also a method for manufacturing a capacitance element that further includes the steps of etching an object (D), the object (D) includes the lower electrode film disposed above the substrate; the dielectric film disposed above the lower electrode film; the upper electrode film disposed above the dielectric film; the inorganic film disposed above the upper electrode film; and the organic resist film disposed above part of the region of the inorganic film, wherein at least part of the surface of the inorganic film and the surface of the organic resist film are exposed. The steps of etching object (D) comprises exposing the object (D) to a plasma of a metal film etching gas, and etching the inorganic film exposed on the surface of the object (D) while the organic resist film is left so as to form the object (C).

The present invention is also a method for manufacturing a capacitance element, wherein the lower electrode etching gas contains oxygen gas and at least one type of gas selected from the group consisting of Cl₂ gas, Br₂ gas, and BCl₃ gas.

The present invention is also a method for manufacturing a capacitance element, wherein the lower electrode film contains platinum, iridium, gold, ruthenium, an indium oxide, a ruthenium oxide, or a strontium ruthenium oxide, the dielectric film is an oxide, and the inorganic film is a titanium film, a TiN film, a TiAlN film, or a laminate of these films.

The present invention is also an etching method for etching an object (A) to be etched, the object (A) is comprised of a lower electrode film disposed above a substrate; a dielectric film disposed above part of a region of the lower electrode film; an upper electrode film disposed above the dielectric film; an inorganic film disposed above the upper electrode film; and an organic resist film disposed above the inorganic film, wherein at least part of the surface of the lower electrode film and the surface of the organic resist film are exposed. The etching method includes the steps of exposing the object (A) to a plasma of a lower electrode etching gas, and etching the organic resist film and the lower electrode film exposed on the surface of the object (A) while the inorganic film is left.

The present invention is also an etching method further includes steps of etching an object (B) to be etched, the object (B) comprising the lower electrode film disposed on the substrate; the dielectric film disposed on the lower electrode film; the upper electrode film disposed on part of a region of the dielectric film; the inorganic film disposed on the upper electrode film; and the organic resist film disposed on the inorganic film, wherein at least part of the surface of the dielectric film and the surface of the organic resist film are exposed, the steps of etching the object (B) includes exposing the object (B) to a plasma of a dielectric film etching gas, and etching the dielectric film exposed on the surface of the object (B) while the organic resist film is left so as to form the object (A).

The present invention is also an etching method that further includes steps of etching an object (C), the object (C) includes the lower electrode film disposed on the substrate; the dielectric film disposed over the lower electrode film; the upper electrode film disposed over the dielectric film; the inorganic film disposed over part of the region of the upper electrode film; and the organic resist film disposed over the inorganic film, wherein at least part of the surface of the upper electrode film and the surface of the organic resist film are exposed, the steps of etching the object (C) includes exposing the object (C) to a plasma of an upper electrode film etching gas, and etching the upper electrode film exposed on the surface of the object (C) while the organic resist film is left, so as to form the object (B).

The present invention is also an etching method that further includes the steps of etching an object (D) to be etched, the object (D) includes the lower electrode film disposed above the substrate; the dielectric film disposed above the lower electrode film; the upper electrode film disposed above the dielectric film; the inorganic film disposed above the upper electrode film; and the organic resist film disposed above part of a region of the inorganic film, wherein at least part of the surface of the inorganic film and the surface of the organic resist film are exposed, the steps of etching the object (D) includes exposing the object (D) to a plasma of a metal film etching gas, and etching the inorganic film exposed on the surface of the object (D) while the organic resist film is left so as to form the object (C).

The present invention is also an etching method, wherein the lower electrode etching gas contains oxygen gas and at least one type of gas selected from the group consisting of Cl₂ gas, Br₂ gas, and BCl₃ gas.

The present invention is also an etching method, wherein the lower electrode film contains platinum, iridium, gold, ruthenium, an indium oxide, a ruthenium oxide, or a strontium ruthenium oxide, the dielectric film is an oxide, and the inorganic film is a titanium film, a TiN film, a TiAlN film, or a laminate of these films.

Accordingly, in this invention, a vertical pattern that is not stepped can be formed. A resist film does not need to be reapplied; and less exposure and developing are needed.

### BRIEF DESCRIPTION OF THE DRAWINGS

FIGS. 1(a) to 1(d) are cross-sectional views (1) illustrating the method of the present invention;

FIGS. 2(a) to 2(c) are cross-sectional views (2) illustrating the method of the present invention;

FIG. 3 is a graph showing the difference in the etching rate depending on whether or not O₂ gas is contained.

### DETAILED DESCRIPTION OF THE PREFERRED EMBODIMENT

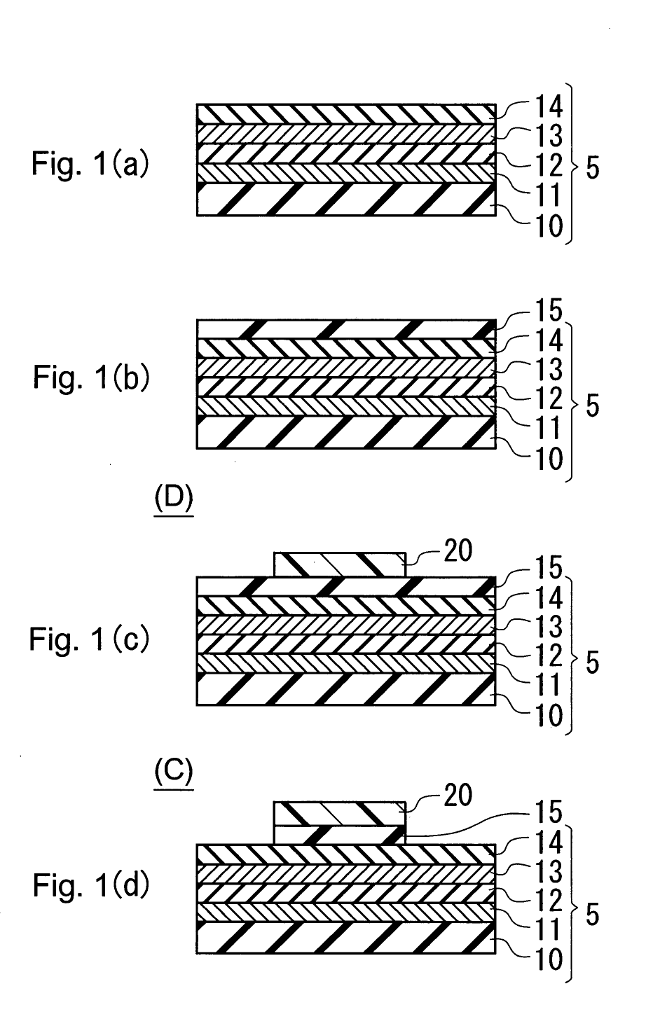

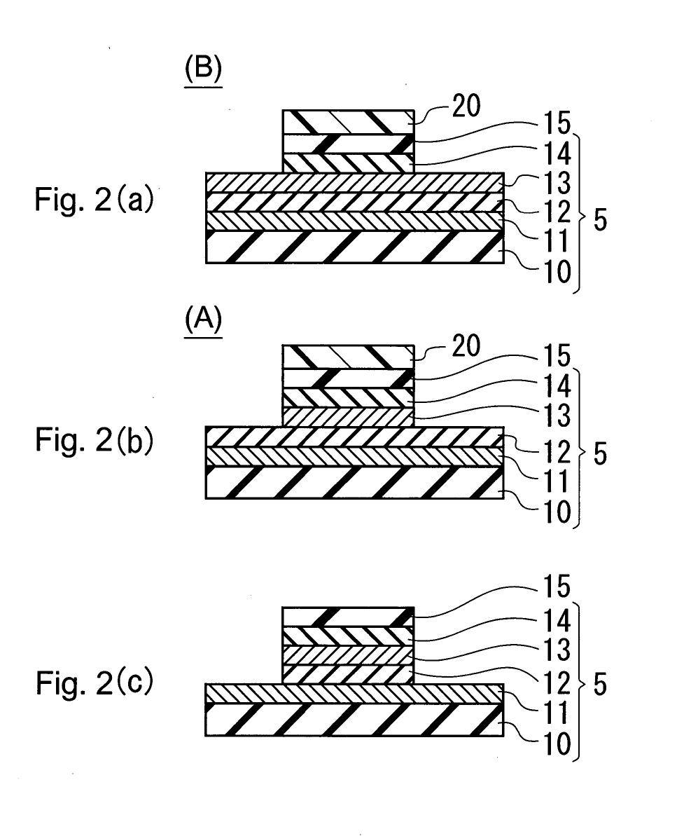

The numeral 5 in FIGS. 1(a) to 1(d) and FIGS. 2(e) to 2(g) indicates the treatment object to which the method of the present invention can be applied.

As shown in FIG. 1(a), this treatment object 5 has a semiconductor substrate 10, and an insulating film 11, a lower electrode film 12, a dielectric film 13, and an upper electrode film 14 are formed in that order, starting from the bottom, on this semiconductor substrate 10.

To pattern the lower electrode film 12, dielectric film 13, and upper electrode film 14 of the treatment object 5 by etching, first, as shown in FIG. 1(b), an inorganic film 15 is formed on the exposed surface of the upper electrode film 14, and then, as shown in FIG. 1(c), a patterned organic resist film 20 is formed on the exposed surface of the inorganic film 15, forming an object (D) to be etched. The surface of the inorganic film 15 is partially covered by the organic resist film 20. The organic resist film 20 is an ordinary photoresist film used for semiconductors, and made from a photoreactive resin, and is patterned by exposure and developing.

This product is conveyed into the reaction chamber of a dry etching apparatus, a first etching gas (metal film etching gas) is introduced into a first reaction chamber, and plasma of the first etching gas is formed. The exposed inorganic film 15 is etched using the organic resist film 20 as a mask, and as shown in FIG. 1(d), the surface of the upper electrode film 14 is partially exposed, forming an object (C) to be etched.

The first etching gas is a gas capable of etching the inorganic film 15 without etching the organic resist film 20 or the upper electrode film 14, and if the inorganic film 15 is a titanium film, tantalum film, zirconium film, hafnium film, a nitride of one of these (such as a TiN film), or a TiAlN film, then the etching gas includes at least one type of gas selected from the group consisting of Cl₂ gas, BCl₃ gas, and Br₂ gas. A rare gas can also be included.

In particular, the titanium etching rate is high, if the first etching gas contains no O₂ gas, and this is preferable for the inorganic film which is a titanium film, a TiN film, or a TiAlN film.

Next, the product is moved to a second reaction chamber without removing the organic resist film 20, a second etching gas (upper electrode etching gas) that is different from the first etching gas is introduced into this second reaction chamber. The second etching gas plasma is formed and the upper electrode film 14 exposed on the surface is etched using the organic resist film 20 as a mask. As a result, the upper electrode film 14 is etched wherever it is not protected by the organic resist film 20 and the inorganic film 15 so that the surface of the dielectric film 13 is partially exposed and the object (B) is formed, as shown in FIG. 2(a).

The second etching gas is a gas that can etch the upper electrode film 14 without etching the organic resist film 20 and the dielectric film 13.

The upper electrode film 14 and the lower electrode film 12 can be constituted by a metal film of platinum, iridium, gold, ruthenium, or an alloy of these, an oxide film such as indium oxide, ruthenium oxide, strontium ruthenium oxide, a laminate of these metal films, a laminate of these oxide films, or a laminate of these metal films and oxide films.

When the upper electrode film 14 and the lower electrode film 12 are constituted by the materials listed above, a mixed gas of BCl₃ gas and a rare gas (such as, argon gas) can be used for the second etching gas.

Next, this product is moved to a third reaction chamber without removing the organic resist film 20, a third etching gas (dielectric etching gas) that is different from the second etching gas is introduced into this third reaction chamber. A third etching gas plasma is formed, and the dielectric film 13 exposed on the surface is etched using the organic resist film 20 as a mask. As a result, the dielectric film 13 is etched wherever it is not protected by the organic resist film 20 and the inorganic film 15 so that the surface of the lower electrode film 12 is partially exposed and the object (A) is formed, as shown in FIG. 2(b). The upper electrode film 14 is located between the remaining dielectric film 13 and the inorganic film 15.

The third etching gas is a gas that can etch the dielectric film 13 without etching the organic resist film 20 and the lower electrode film 12. When the dielectric film 13 is an oxide dielectric film and also a film of paraelectric oxide; such as, (Ba, Sr)Tio₂, SrTio₃, or a film of ferroelectric; such as, SrBi₂Ta₂O₉, Bi₄Ti₃O₁₂,Pb(Zr, Ti)O₃, (Bi, La)₄Ti₅O₁₂, the third etching gas can include a rare gas such as argon gas, and C₄F₈ gas, and at least one type of gas selected from among BCl₃ gas, HBr gas, and Cl₂ gas.

The organic resist film 20 becomes thinner while the inorganic film 15, the upper electrode film 14, and the dielectric film 13 are being etched in that order with the first to third etching gases, but the organic resist film 20 still remains after completion of the etching of the dielectric film 13.

Next, this product is moved to a fourth reaction chamber without removing the organic resist film 20, a fourth etching gas (lower electrode etching gas) that can etch the organic resist film 20 and the lower electrode film 12 is introduced into the fourth reaction chamber, and a plasma of this gas is formed.

In the above-mentioned etching of the upper electrode film 14, the organic resist film 20 is not etched, but in the etching of the lower electrode film 12, the organic resist film 20 is etched.

Therefore, no O₂ gas is included in the second etching gas that etches the upper electrode film 14, O₂ gas is included in the fourth etching gas that etches the lower electrode film 12 so that organic matter and metals and their compounds are both etched. The fourth etching gas used here is a mixed gas of a rare gas (such as, argon gas) along with Cl₂ gas and O₂ gas.

If the fourth etching gas contains O₂ gas in a proportion of greater than 25% in volume ratio, the organic resist film 20 will be quickly removed.

At the start of the etching, the organic resist film 20 serves as a mask as the etching of the lower electrode film 12 proceeds, but the organic resist film 20 has a high etching rate.

In the present invention, the etching of the lower electrode film 12 is not completed when the organic resist film 20 is removed by the fourth etching gas and the surface of the inorganic film 15 is exposed.

The inorganic film 15 is not etched by the fourth etching gas, and the inorganic film 15 serves as a mask after the organic resist film 20 has been removed, the etching of the lower electrode film 12 whose surface is partially exposed proceeds in a state in which the portion covered by the inorganic film 15 is protected. The exposed portion of the lower electrode film 12 is removed, and the insulating film 11 is exposed as shown in FIG. 2(c). Consequently, a capacitance element is obtained from the lower electrode film 12, dielectric film 13, and upper electrode film 14, each of which has been patterned.

Since the organic resist film remains behind in the etching of the lower electrode film 12, when an etching gas containing no O₂ gas is used, the etching product including carbon is produced by reaction between the etching gas plasma and the residual organic resist film. This product tends to be redeposited on the side walls of the pattern. Therefore, it is preferable that the organic resist film 20 does not remain behind when the lower electrode film 12 is etched using an etching gas containing no O₂ gas.

A large amount of O₂ gas cannot be contained in the etching gas for an oxide dielectric. It is also undesirable to provide a dedicated ashing chamber in order for the organic resist film 20 to be ashed away after the etching of the dielectric film 13, because this will increase the number of steps involved.

The fourth etching gas of the present invention comprises O₂ gas added to the gas that etches the lower electrode film 12, and since the etching of the organic resist film 20 is performed continuously with the etching of the lower electrode film 12, the organic resist film 20 can be removed quickly and without adding any more steps. The organic resist film 20 will be removed particularly fast if the O₂ gas is contained in an amount of at least 25 vol %.

Also, if the inorganic film 15 is exposed to an etching gas plasma containing O₂ gas, an oxide film of the material that makes up the inorganic film 15 will be formed on the surface of the inorganic film 15, and etching will no longer proceed, and the portion covered by the inorganic film 15 being protected. Setting the concentration of O₂ gas to at least 25% is effective for forming an oxide film on the surface of the inorganic film 15.

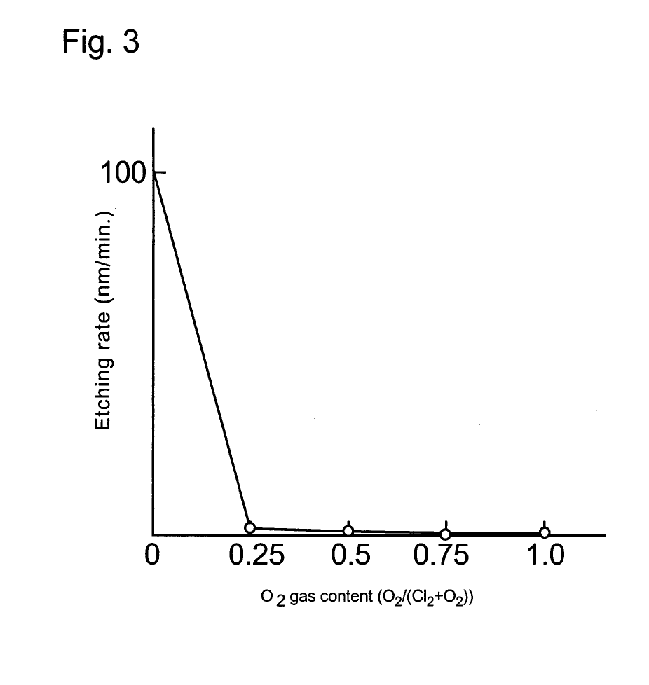

The graph in FIG. 3 shows the relationship of the etching rate to the O₂ gas content (vol %) when the inorganic film 15 composed of a TiN film is etched with a mixed gas of Cl₂ gas and O₂ gas. When no O₂ gas is included, the rate is 100 nm/minute, but at a content of at least 25 vol %, the rate dropped to substantially 0 nm/minute.

Furthermore, because the same region is covered by the inorganic film 15 and the organic resist film 20, and everything from the upper electrode film 14 to the lower electrode film 12 is etched without reapplying a resist film, the etching shape is vertical and there is less dimensional shift.

In the above working example the upper electrode film 14 and the lower electrode film 12 are each a single-layer film, but the upper electrode film 14 and the lower electrode film 12 in the present invention may instead be multilayer films obtained by laminating one or more types of film.

Also, the reaction chamber is changed for each film being etched in the above working example, but everything from the inorganic film 15 to the lower electrode film 12 may instead be continuously etched in the same reaction chamber.

What is claimed is:

1. A method for manufacturing a capacitance element to manufacture a capacitance element in which the lower electrode film, the dielectric film, and the upper electrode film are laminated, by etching an object (A) to be etched, wherein the object (A) includes:
a lower electrode film disposed above a substrate;
a dielectric film disposed above part of a region of the lower electrode film,
an upper electrode film disposed above the dielectric film,
an inorganic film disposed above the upper electrode film, and
an organic resist film disposed above the inorganic film,
wherein at least part of the surface of the lower electrode film and the surface of the organic resist film are exposed,
the manufacturing method comprising the steps of:
exposing the object (A) to a plasma of a lower electrode etching gas; and
etching the organic resist film and the lower electrode film exposed on the surface of the object (A) while the inorganic film is left.

2. The method for manufacturing a capacitance element according to claim 1, further comprising steps of etching an object(B) to be etched, wherein the object(B) includes:
the lower electrode film disposed above the substrate,
the dielectric film disposed above the lower electrode film,
the upper electrode film disposed above part of a region of the dielectric film,
the inorganic film disposed above the upper electrode film, and
the organic resist film disposed above the inorganic film,
wherein at least part of the surface of the dielectric film and the surface of the organic resist film are exposed,
the steps of etching the object (B) comprising the steps of:
exposing the object (B) to a plasma of a dielectric film etching gas; and
etching the dielectric film exposed on the surface of the object (B) while the organic resist film is left so as to form the object (A).

3. The method for manufacturing a capacitance element according to claim 2, further comprising steps of etching an object (C) to be etched, wherein the object (C) includes:
the lower electrode film disposed above the substrate,
the dielectric film disposed above the lower electrode film,
the upper electrode film disposed above the dielectric film,
the inorganic film disposed on part above a region of the upper electrode film, and
the organic resist film disposed above the inorganic film,
wherein at least part of the surface of the upper electrode film and the surface of the organic resist film are exposed,
the steps of etching the object (C) comprising the steps of:
exposing the object (C) to a plasma of an upper electrode film etching gas; and
etching the upper electrode film exposed on the surface of the object (C) while the organic resist film is left so as to form the object (B).

4. The method for manufacturing a capacitance element according to claim 3, further comprising steps of etching an object (D) to be etched, wherein the object (D) includes:
the lower electrode film disposed above the substrate,
the dielectric film disposed above the lower electrode film,
the upper electrode film disposed above the dielectric film,
the inorganic film disposed above the upper electrode film, and
the organic resist film disposed above part of a region of the inorganic film,
wherein at least part of the surface of the inorganic film and the surface of the organic resist film are exposed,
the steps of etching the object (D) comprising the steps of:
exposing the object (D) to a plasma of a metal film etching gas; and
etching the inorganic film exposed on the surface of the object (D) while the organic resist film is left so as to form the object (C).

5. The method for manufacturing a capacitance element according to claim 1, wherein the lower electrode etching gas includes oxygen gas and at least one type of gas selected from the group consisting of Cl₂ gas, Br₂ gas, and BCl₃ gas.

6. The method for manufacturing a capacitance element according to claim 5, wherein the lower electrode film includes platinum, iridium, gold, ruthenium, an indium oxide, a ruthenium oxide, or a strontium ruthenium oxide,
the dielectric film is an oxide, and
the inorganic film is a titanium film, a TiN film, a TiAlN film, or a laminate of these films.

7. An etching method etching an object (A) to be etched, wherein the object (A) includes:
a lower electrode film disposed above a substrate;
a dielectric film disposed above part of a region of the lower electrode film,
an upper electrode film disposed above the dielectric film,
an inorganic film disposed above the upper electrode film, and
an organic resist film disposed above the inorganic film,
wherein at least part of the surface of the lower electrode film and the surface of the organic resist film are exposed,
the etching method comprising the steps of:
exposing the object (A) to a plasma of a lower electrode etching gas; and
etching the organic resist film and the lower electrode film exposed on the surface of the object (A) while the inorganic film is left.

8. The etching method according to claim 7, further comprising steps of etching an object (B) to be etched, wherein the object (B) includes:
the lower electrode film disposed on the substrate,
the dielectric film disposed on the lower electrode film,
the upper electrode film disposed on part of a region of the dielectric film,
the inorganic film disposed on the upper electrode film, and
the organic resist film disposed on the inorganic film,
wherein at least part of the surface of the dielectric film and the surface of the organic resist film are exposed,
the steps of etching the object (B) comprising the steps of:
exposing the object (B) to a plasma of a dielectric film etching gas; and
etching the dielectric film exposed on the surface of the object (B) while the organic resist film is left so as to form the object (A).

9. The etching method according to claim 8, further comprising the step of etching an object (C) to be etched, wherein the object (C) includes:
the lower electrode film disposed above the substrate,
the dielectric film disposed above the lower electrode film,
the upper electrode film disposed above the dielectric film,
the inorganic film disposed above part of a region of the upper electrode film, and
the organic resist film disposed above the inorganic film,
wherein at least part of the surface of the upper electrode film and the surface of the organic resist film are exposed,
the steps of etching the object (C) comprising the steps of:
exposing the object (C) to a plasma of an upper electrode film etching gas; and
etching the upper electrode film exposed on the surface of the object (C) while the organic resist film is left so as to form the object (B).

10. The etching method according to claim 9, further comprising the step of etching an object (D) to be etched, wherein the object (D) includes:
the lower electrode film disposed above the substrate,
the dielectric film disposed above the lower electrode film,
the upper electrode film disposed above the dielectric film,
the inorganic film disposed above the upper electrode film, and
the organic resist film disposed above part of a region of the inorganic film,
wherein at least part of the surface of the inorganic film and the surface of the organic resist film are exposed,
the steps of etching the object (D) comprising the steps of:
exposing the object (D) to a plasma of a metal film etching gas; and
etching the inorganic film exposed on the surface of the object (D) while the organic resist film is left so as to form the object (C).

11. The etching method according to claim 7, wherein the lower electrode etching gas includes oxygen gas and at least one type of gas selected from the group consisting of Cl₂ gas, Br₂ gas, and BCl₃ gas.

12. The etching method according to claim 11, wherein the lower electrode film includes platinum, iridium, gold, ruthenium, an indium oxide, a ruthenium oxide, or a strontium ruthenium oxide,
the dielectric film is an oxide, and
the inorganic film is a titanium film, a TiN film, a TiAlN film, or a laminate of these films.
